(19) United States
(12) Patent Application Publication
(10) Pub. No.: US 2026/0202190 A1
(43) Pub. Date: Jul. 16, 2026

(54) INFORMATION GATHERING SYSTEM, SUBSTRATE FOR INSPECTION, AND INFORMATION GATHERING METHOD

(71) Applicant: Tokyo Electron Limited, Tokyo (JP)

(72) Inventors: Junnosuke MAKI, Kumamoto (JP); Nobuyuki SATA, Kumamoto (JP); Masato HAYASHI, Kumamoto (JP)

(21) Appl. No.: 18/865,928

(22) PCT Filed: May 8, 2023
(86) PCT No.: PCT/JP2023/017273

§ 371 Date: Nov. 14, 2024

(30) Foreign Application Priority Data
May 18, 2022 (JP) 2022-081409

(51) Int. Cl. G01B 11/14; G06T 7/70; H10P 72/00

(52) U.S. Cl. CPC G01B 11/14; G06T 7/70; H10P 72/0606; G06T 2207/20056; G06T 2207/30148

(57) ABSTRACT

Provided is a technique capable of acquiring information on the distance between a functional member and a substrate within a substrate processing apparatus. An information collection system that acquires information on a substrate processing apparatus including a substrate holder configured to hold a substrate and an annular member located in a backside of the substrate, includes a disk-shaped main body having a bottom surface held by the substrate holder, an irradiator fixed to the main body and configured to irradiate the annular member with a measurement wave, a detector fixed to the main body and configured to detect a response to the measurement wave from the irradiator, and a calculator configured to acquire information on a gap between the main body and the annular member based on the response detected by the detector.

This is a National Phase Application filed under 35 U.S.C. 371 as a national stage of PCT/JP2023/017273, filed May 8, 2023, an application claiming the benefit of Japanese Application on No. 2022-081409, filed May 18, 2022, the content of each of which is hereby incorporated by reference in its entirety.

### TECHNICAL FIELD

The present disclosure relates to an information collection system, an inspection substrate, and an information collection method.

### BACKGROUND

In the manufacturing process of semiconductor devices, semiconductor wafers are transferred to a substrate processing apparatus while being stored in a carrier and are then subjected to a processing. Examples of this processing may include a liquid processing such as the formation or development of a coating film through the supply of a coating liquid. During that liquid processing, a processing liquid is supplied from a nozzle to a wafer received in a cup. Patent Document 1 describes a development apparatus that includes a cup having an annular protrusion facing a lower surface of a wafer.

### PRIOR ART DOCUMENT

### Patent Document

Patent Document 1: Japanese laid-open publication No. 2020-013932

The present disclosure provides a technique capable of acquiring information on the distance between a functional member and a substrate within a substrate processing apparatus.

### SUMMARY

According to one embodiment of the present disclosure, there is provided an information collection system that acquires information on a substrate processing apparatus including a substrate holder configured to hold a substrate and an annular member located in a backside of the substrate, the information collection system including a disk-shaped main body having a bottom surface that is capable of being held by the substrate holder, an irradiator fixed to the main body and configured to irradiate the annular member with a measurement wave, a detector fixed to the main body and configured to detect a response to the measurement wave from the irradiator, and a calculator configured to acquire information on a gap between the main body and the annular member based on the response detected by the detector.

According to the present disclosure, it is possible to provide a technique capable of acquiring information on the distance between a functional member and a substrate within a substrate processing apparatus.

### BRIEF DESCRIPTION OF DRAWINGS

FIG. 1 is a diagram illustrating a schematic configuration example of an information collection system according to one exemplary embodiment.

FIG. 2 is a diagram illustrating a schematic configuration example of the information collection system according to one exemplary embodiment.

FIG. 3 is a diagram illustrating a schematic configuration example of a coating unit in a coating/development apparatus.

FIG. 4 is a diagram illustrating a relationship example between an inspection wafer, a controller, and an information collection device.

FIG. 5 is a diagram illustrating a hardware configuration example of the inspection wafer, the controller, and the information collection device.

FIG. 6 is a diagram illustrating a configuration example of a distance estimator of the inspection wafer.

FIGS. 7A and 7B are diagrams illustrating a configuration example of the distance estimator of the inspection wafer.

FIGS. 8A and 8B are diagrams illustrating an example of a processing related to an image captured from the inspection wafer.

FIG. 9 is a diagram illustrating an example of a model for calculating a distance used in a calculator.

FIG. 10 is a diagram illustrating an example of a processing in the calculator of the inspection wafer.

FIG. 11 is a diagram illustrating an example of a processing in the calculator of the inspection wafer.

FIG. 12 is a diagram illustrating an example of a processing in the calculator of the inspection wafer.

FIGS. 13A and 13B are diagrams illustrating an example of a processing in the calculator of the inspection wafer.

FIG. 14 is a sequence diagram illustrating an example of a processing procedure between respective apparatuses in the information collection system according to one embodiment.

FIG. 15 is a sequence diagram illustrating an example of a processing procedure between respective apparatuses in the information collection system according to one embodiment.

### DETAILED DESCRIPTION

Hereinafter, various exemplary embodiments will be described.

In one exemplary embodiment, an information collection system is provided. The information collection system that acquires information on a substrate processing apparatus including a substrate holder configured to hold a substrate and an annular member located in a backside of the substrate, includes a disk-shaped main body having a bottom surface that is capable of being held by the substrate holder, an irradiator fixed to the main body and configured to irradiate the annular member with a measurement wave, a detector fixed to the main body and configured to detect a response to the measurement wave from the irradiator, and a calculator configured to acquire information on a gap between the main body and the annular member based on the response detected by the detector.

According to the above-described information collection system, the annular member is irradiated with a measurement wave from the irradiator fixed to the disk-shaped main body, the response to the measurement wave from the irradiator is detected by the detector fixed to the main body, and the information on the gap between the main body and the annular member is acquired from the response result. Since the main body is capable of being held by the substrate holder, this configuration enables the acquisition of information on the distance between a functional member and the substrate within the substrate processing apparatus.

In an embodiment, the irradiator may emit light as the measurement wave, and the detector may be a camera that captures an image of the annular member irradiated with the light.

In this case, the calculator acquires the information on the gap between the main body and the annular member using the image captured by the camera. With a configuration where various types of information contained in the image are used to acquire the gap information, it is possible to acquire more accurate information on the distance between the functional member and the substrate within the substrate processing apparatus.

In an embodiment, the light emitted from the irradiator may be strip-shaped light, the annular member may be irradiated with the strip-shaped light from a direction other than perpendicular to an upper end of the annular member, such that the light extends in a direction intersecting a circumferential direction of the annular member, and the calculator may identify a light irradiation position of the strip-shaped light on the annular member from an image captured by the camera, and acquires the information on the gap between the main body and the annular member based on the identified information.

Using the strip-shaped light makes it easier to emit the strip-shaped light to the annular member even if the relative position between the annular member and the main body changes slightly. Further, when the annular member is irradiated with the strip-shaped light from a direction other than perpendicular to the upper end of the annular member, the light irradiation position of the strip-shaped light on the annular member changes depending on the distance between the main body and the annular member. Therefore, the calculator is configured to identify the light irradiation position of the strip-shaped light on the annular member and to calculate the gap between the main body and the annular member based on the identified information, so that it is possible to acquire more accurate information on the distance between the functional member and the substrate within the substrate processing apparatus.

In an embodiment, the calculator may acquire the information on the gap between the main body and the annular member based on a model that illustrates a relationship between the light irradiation position of the strip-shaped light on the annular member and the gap between the main body and the annular member.

As described above, with a configuration where the gap between the main body and the annular member is calculated based on the model, it is possible to acquire more accurate information regarding the distance between the functional member and the substrate within the substrate processing apparatus.

In an embodiment, the calculator may calculate a change in light intensity distribution in a circumferential direction of the annular member from information on the light intensity distribution included in the image captured by the camera, and may identify the light irradiation position of the strip-shaped light on the annular member from the change information.

With the above configuration, it is possible to more accurately identify the light irradiation position of the strip-shaped light, enabling the acquisition of more accurate information on the distance between the functional member and the substrate within the substrate processing apparatus.

In an embodiment, an upper surface of the annular member may contain repeated unevenness along the circumferential direction, and the calculator may apply Fast Fourier Transform to the image captured by the camera to remove, from the image, a frequency component of an intensity of light that is repeated along the circumferential direction of the annular member, and may identify the light irradiation position of the strip-shaped light on the annular member.

If the upper surface of the annular member has repeated unevenness along the circumferential direction, scattered light due to this unevenness may make it difficult to accurately identify the light irradiation position of the strip-shaped light. In such a case, using Fast Fourier Transform as described to remove the frequency component as described allows for more accurate identification of the light irradiation position of the strip-shaped light.

In an embodiment, the annular member may be a liquid processing cup that is located in the backside of the substrate and includes a backside liquid receiving portion with a protrusion designed to prevent a processing liquid supplied to the substrate from flowing to the backside of the substrate, and the gap between the main body and the annular member may be a gap between the main body and the protrusion of the backside liquid receiving portion.

Since the protrusion of the backside light receiving portion is a member positioned in proximity to the substrate, accurately determining the distance between them is required. Therefore, with the above configuration, it is possible to more accurately determine the distance between the substrate and the protrusion.

Further, in an embodiment, the information collection system may further include an information collection device capable of communicating with a controller that controls the substrate processing apparatus, and an inspection substrate capable of communicating with the information collection device and including the main body, the irradiator, and the detector, and the irradiator and the detector may operate based on an instruction from the information collection device.

At this time, in an embodiment, the calculator may be provided in the inspection substrate, and may operate based on the instruction from the information collection device. Further, in an embodiment, the calculator may be provided in the information collection device.

In one exemplary embodiment, an inspection substrate is provided. The inspection substrate that acquires information on a substrate processing apparatus comprising a substrate holder configured to hold a substrate and an annular member located in a backside of the substrate, includes a disk-shaped main body having a bottom surface that is capable of being held by the substrate holder, an irradiator fixed to the main body and configured to irradiate the annular member with a measurement wave, and a detector fixed to the main body and configured to detect a response to the measurement wave from the irradiator.

According to the above inspection substrate, the annular member is irradiated with the measurement wave from the irradiator fixed to the disk-shaped main body, the response to the measurement wave from the irradiator is detected by the detector fixed to the main body, and information on the gap between the main body and the annular member is acquired from the response result. Since the main body is capable of being held by the substrate holder, this configuration enables the acquisition of distance information between the functional member and the substrate within the substrate processing apparatus.

In an embodiment, the inspection substrate may further include a calculator configured to acquire information on a gap between the main body and the annular member based on the response detected by the detector.

In one exemplary embodiment, an information collection method is provided. The information collection method of acquiring information on a substrate processing apparatus including a substrate holder configured to hold a substrate and an annular member located in a backside of the substrate, includes holding a bottom surface of a disk-shaped main body by the substrate holder, irradiating the annular member with a measurement wave using an irradiator fixed to the main body, detecting a response to the measurement wave from the irradiator using a detector fixed to the main body, and acquiring information on a gap between the main body and the annular member using a calculator based on the response detected by the detector.

According to the above information collection method, the annular member is irradiated with the measurement wave from the irradiator fixed to the disk-shaped main body, the response to the measurement wave from the irradiator is detected by the detector fixed to the main body, and the information on the gap between the main body and the annular member is acquired from the response result. Since the main body is capable of being held by the substrate holder, this configuration enables the acquisition of distance information between the functional member and the substrate within the substrate processing apparatus.

In an embodiment, in the irradiating, the irradiator may emit light as the measurement wave, and the detector may be a camera that captures an image of the annular member irradiated with the light.

In this case, the calculator acquires information on the distance between the main body and the annular member using the image captured by the camera. By utilizing various types of information contained in the image to acquire the gap information, it is possible to acquire more accurate information on the distance between the functional member and the substrate within the substrate processing apparatus.

In an embodiment, in the irradiating, the light emitted from the irradiator may be strip-shaped light, the annular member may be irradiated with the strip-shaped light from a direction other than perpendicular to an upper end of the annular member, such that the light extends in a direction intersecting a circumferential direction of the annular member, and in the acquiring, the calculator may identify a light irradiation position of the strip-shaped light on the annular member from an image captured by the camera, and may acquire the information on the gap between the main body and the annular member based on the identified information.

Using the strip-shaped light makes it easier to emit the strip-shaped light to the annular member even if the relative position between the annular member and the main body changes slightly. Further, when the strip-shaped light is emitted to the annular member from a direction other than perpendicular to the upper end of the annular member, the light irradiation position of the strip-shaped light on the annular member changes depending on the distance between the main body and the annular member. Therefore, with a configuration where the calculator identifies the light irradiation position of the strip-shaped light on the annular member and calculates the distance between the main body and the annular member based on the identified information, it is possible to acquire more accurate information on the distance between the functional member and the substrate within the substrate processing apparatus.

In an embodiment, in the acquiring, the calculator may acquire the information on the gap between the main body and the annular member based on a model that illustrates a relationship between the light irradiation position of the strip-shaped light on the annular member and the gap between the main body and the annular member.

With a configuration where the calculator calculates the gap between the main body and the annular member based on the model as described above, it is possible to acquire more accurate information on the distance between the functional member and the substrate within the substrate processing apparatus.

In an embodiment, in the acquiring, the calculator may calculate a change in light intensity distribution in a circumferential direction of the annular member from information on the light intensity distribution included in the image captured by the camera, and may identify the light irradiation position of the strip-shaped light on the annular member from the change information.

With the above configuration, it is possible to more accurately identify the light irradiation position of the strip-shaped light, enabling the acquisition of more accurate information on the distance between the functional member and the substrate within the substrate processing apparatus.

In an embodiment, an upper surface of the annular member may contain repeated unevenness along the circumferential direction, and in the acquiring, the calculator may apply Fast Fourier Transform to the image captured by the camera to remove, from the image, a frequency component of an intensity of light that is repeated along the circumferential direction of the annular member, and may identify the light irradiation position of the strip-shaped light on the annular member.

If the upper surface of the annular member has repeated unevenness along the circumferential direction, scattered light due to the unevenness may make it difficult to accurately identify the light irradiation position of the strip-shaped light. In such a case, using Fast Fourier Transform to remove the frequency components as described allows for more accurate identification of the light irradiation position of the strip-shaped light.

### Exemplary Embodiment

Hereinafter, various exemplary embodiments will be described in detail with reference to the drawings. In addition, the same reference numerals will be given to the same or corresponding parts in each drawing.

### Information Collection System

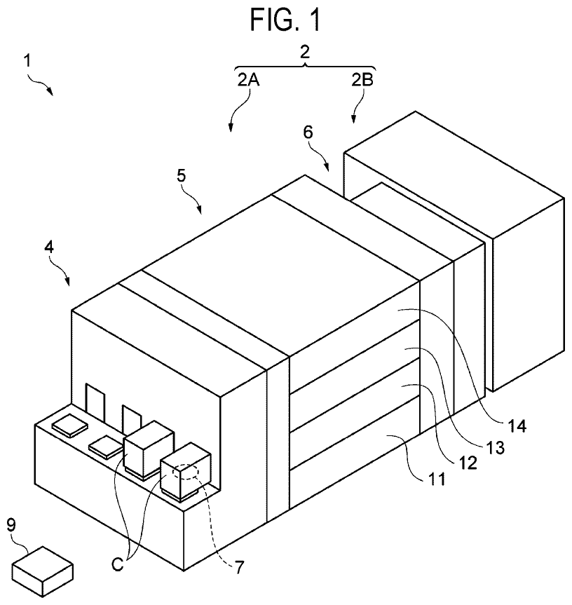

An information collection system 1 according to one embodiment of the present disclosure is illustrated in FIG. 1. The information collection system 1 includes a substrate processing system 2, an inspection wafer 7 (inspection substrate), and an information collection device 9.

The substrate processing system 2 transfers a workpiece W, which is a circular substrate, between processing modules by a transfer mechanism to perform a processing. This processing includes the formation of a resist film in a processing module designed for resist film formation, where a resist is supplied to the workpiece W received in a cup.

The inspection wafer 7 is transferred, instead of the workpiece W, into the substrate processing system 2 by the transfer mechanism. The inspection wafer 7 functions to capture an image of an upper ring end constituting the cup to acquire image data and to acquire information on the distance (gap) between the workpiece W and the upper ring end when the workpiece W is placed on the processing module.

The information collection device 9 controls the inspection wafer 7 and acquires estimation results transmitted from the inspection wafer 7. Further, based on this information, the information collection device 9 acquires information on the distance between the workpiece W and the substrate processing system 2 before the processing of the workpiece W by the substrate processing system 2, thereby preventing an abnormal processing when forming a resist film on the workpiece W.

### Substrate Processing System

The substrate processing system 2 includes a coating/development apparatus 2A, an exposure apparatus 2B, and a controller 100 (control unit). The exposure apparatus 2B is an apparatus that exposes a resist film (photosensitive film) formed on the workpiece W (substrate). Specifically, the exposure apparatus 2B irradiates an exposure target portion of the resist film with energy rays by a method such as liquid immersion exposure. The coating/development apparatus 2A performs, before the exposure by the exposure apparatus 2B, the formation of a resist film by coating a surface of the workpiece W with a resist (chemical liquid) and then, after the exposure, performs the development of the resist film. In addition, a processing module, targeted for inspection using the above-described inspection wafer 7, is provided in the coating/development apparatus 2A. Therefore, in the following embodiments, the coating/development apparatus 2A will be described as a substrate processing apparatus.

### Substrate Processing Apparatus

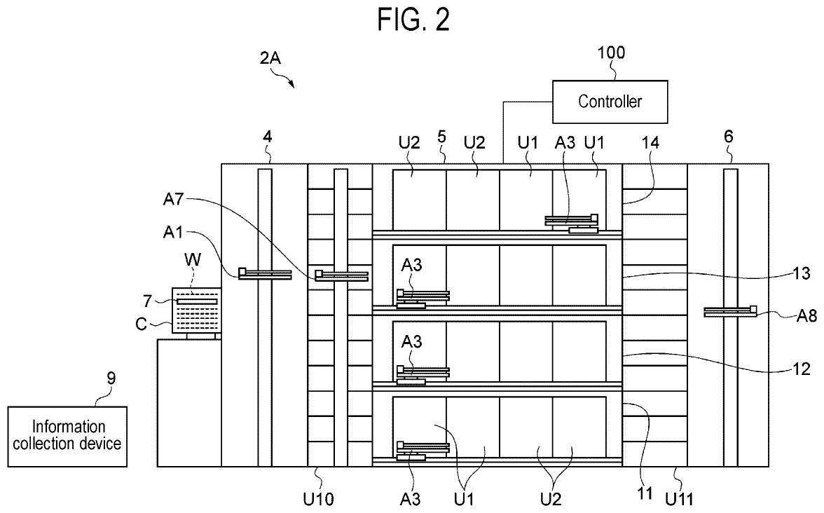

A configuration of the coating/development apparatus 2A will be described as an example of a substrate processing apparatus. As illustrated in FIGS. 1 and 2, the coating/development apparatus 2A includes a carrier block 4, a processing block 5, and an interface block 6.

The carrier block 4 performs the introduction of the workpiece W into the coating/development apparatus 2A and the extraction of the workpiece W out of the coating/development apparatus 2A. For example, the carrier block 4 is capable of supporting a plurality of carriers C for the workpiece W and is equipped with a transfer device Al including a transfer arm. The carrier C accommodates, for example, a plurality of circular workpieces W. The transfer device A1 extracts the workpiece W from the carrier C to send it to the processing block 5 and then, receives the workpiece W from the processing block 5 to return it into the carrier C. The processing block 5 includes a plurality of processing modules 11, 12, 13 and 14.

The processing module 11 is equipped with a coating unit U1, a thermal processing unit U2, and a transfer device A3 that transfers the workpiece W to these units. The processing module 11 forms a lower layer film on a surface of the workpiece W using the coating unit U1 and the thermal processing unit U2. The coating unit U1 applies a processing liquid for lower layer film formation onto the workpiece W. The thermal processing unit U2 performs various types of thermal processing accompanied by the formation of the lower layer film.

The processing module (liquid processing unit) 12 is equipped with the coating unit U1, the thermal processing unit U2, and the transfer device A3 that transfers the workpiece W to these units. The processing module 12 performs a liquid processing including the formation of a resist film on the lower layer film using the coating unit U1 and the thermal processing unit U2. The coating unit U1 applies a processing liquid (resist) for resist film formation onto the lower layer film. The thermal processing unit U2 performs various types of thermal processing accompanied by coating formation. In addition, the coating unit U1 functions to form a coating film using a resist liquid on the circumferential edge of the workpiece W.

The processing module 13 is equipped with the coating unit U1, the thermal processing unit U2, and the transfer device A3 that transfers the workpiece W to these units. The processing module 13 forms an upper layer film on the resist film using the coating unit U1 and the thermal processing unit U2. The coating unit U1 applies a liquid for upper layer film formation onto the resist film. The thermal processing unit U2 performs various types of thermal processing accompanied by the formation of the upper layer film.

The processing module 14 is equipped with the coating unit U1, the thermal processing unit U2, and the transfer device A3 that transfers the workpiece W to these units. The processing module 14 performs the development of the resist film, which has subjected to exposure, and a thermal processing accompanied by the development using the coating unit U1 and the thermal processing unit U2. The coating unit U1 performs the development of the resist film by applying a developer liquid onto the surface of the completely exposed workpiece W and then, washing the developer liquid away with a rinse liquid. The thermal processing unit U2 performs various types of thermal processing accompanied by the development. Specific examples of thermal processing may include heating before the development (e.g., Post Exposure Bake (PEB)) and heating after the development (e.g., Post Bake (PB)).

A shelf unit U10 is provided within the processing block 5 on the carrier block 4 side. The shelf unit U10 is divided into a plurality of cells arranged in the vertical direction. A transfer device A7 including a lifting arm is provided in the vicinity of the shelf unit U10. The transfer device A7 raises or lowers the workpiece W between the cells of the shelf unit U10.

A shelf unit U11 is provided within the processing block 5 on the interface block 6 side. The shelf unit U11 is divided into a plurality of cells arranged in the vertical direction.

The interface block 6 performs the delivery of the workpiece W to and from the exposure apparatus 2B. For example, the interface block 6 is equipped with a transfer device A8 including a transfer arm and is connected to the exposure apparatus 2B. The transfer device A8 sends the workpiece W placed on the shelf unit U11 to the exposure apparatus 2B. The transfer device A8 receives the workpiece W from the exposure apparatus 2B and returns it to the shelf unit U11.

The control of the above-described coating/development apparatus 2A is performed by the controller 100. The controller 100 retains information regarding a processing procedure for executing a processing related to the workpiece W in the coating/development apparatus 2A, and controls each part to load the workpiece W into the coating/development apparatus 2A and execute a desired processing. In addition, the controller 100 functions to transmit and receive information to and from the information collection device 9 to be described later and to notify the information collection device 9 of, e.g., a transfer status when the inspection wafer 7 to be described later is loaded into the coating/development apparatus 2A.

A processing of the workpiece W executed in the substrate processing system 2 will be described. The controller 100 controls the coating/development apparatus 2A to execute a processing of the workpiece W, for example, in the following sequence. First, the controller 100 controls the transfer device A1 to transfer the workpiece W from the carrier C to the shelf unit U10 and then, controls the transfer device A7 to place the workpiece W in the cell for the processing module 11.

Subsequently, the controller 100 controls the transfer device A3 to transfer the workpiece W from the shelf unit U10 to the coating unit U1 and thermal processing unit U2 of the processing module 11. Further, the controller 100 controls the coating unit U1 and thermal processing unit U2 to form the lower layer film on the surface the workpiece W. After that, the controller 100 controls the transfer device A3 to return the workpiece W, on which the lower layer film has been formed, to the shelf unit U10 and then, controls the transfer device A7 to place the workpiece W in the cell for the processing module 12.

Subsequently, the controller 100 controls the transfer device A3 to transfer the workpiece W from the shelf unit U10 to the coating unit U1 and thermal processing unit U2 of the processing module 12. The controller 100 controls the coating unit U1 and thermal processing unit U2 to form the resist film on the lower layer film of the workpiece W. An example of a liquid processing method performed in the processing module 12 will be described later. After that, the controller 100 controls the transfer device A3 to return the workpiece W to the shelf unit U10 and then, controls the transfer device A7 to place the workpiece W in the cell for the processing module 13.

Subsequently, the controller 100 controls the transfer device A3 to transfer the workpiece W from the shelf unit U10 to the coating unit U1 and processing unit U2 of the processing module 13. Further, the controller 100 controls the coating unit U1 and thermal processing unit U2 to form the upper layer film on the resist film of the workpiece W. After that, the controller 100 controls the transfer device A3 to transfer the workpiece W to the shelf unit U11.

Subsequently, the controller 100 controls the transfer device A8 to send the workpiece W accommodated in the shelf unit U11 to the exposure apparatus 2B. Then, the resist film formed on the workpiece W is exposed in the exposure apparatus 2B. After that, the controller 100 receives the exposed workpiece W from the exposure apparatus 2B and then, controls the transfer device A8 to place that workpiece W in the cell of the shelf unit U11 for the processing module 14.

Subsequently, the controller 100 controls the transfer device A3 to transfer the workpiece W from the shelf unit U11 to the thermal processing unit U2 of the processing module 14. Then, the controller 100 controls the coating unit U1 and thermal processing unit U2 to execute development and thermal processing accompanied by the development. By the above, the controller 100 ends a substrate processing for a single workpiece W.

### Coating Unit

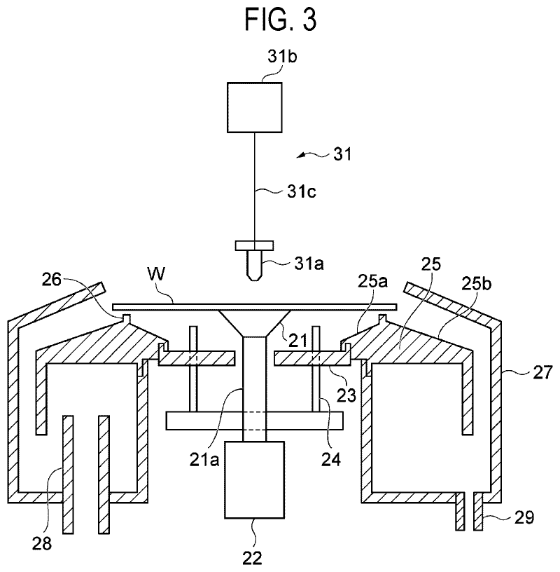

Next, the coating unit U1 of the processing module 12 will be described in detail. As illustrated in FIG. 3, the coating unit U1 of the processing module 12 includes a spin chuck 21 (substrate holder), a rotation drive 22, support pins 24, a guide ring 25, a cup 27, an exhaust pipe 28, and a drain port 29. Further, the coating unit U1 includes a processing liquid supplier 31. Although multiple types of processing liquid suppliers 31 may be provided, only one type is illustrated by way of example in the present embodiment.

The spin chuck 21 holds the workpiece W horizontally. The spin chuck 21 is connected to the rotation drive 22 via a shaft 21a that extends in the vertical direction. The rotation drive 22 rotates the spin chuck 21 at a predetermined rotational speed based on a control signal output from the controller 100.

A protective plate 23 is provided around the shaft 21a, and the support pins 24 pass through that protective plate 23 to extend in the vertical direction. The support pins 24 are pins capable of supporting the backside of the workpiece W. As an example, three such pins are provided around the shaft of the spin chuck 21. The support pins 24 may be raised or lowered by a lifting mechanism (not illustrated). The support pins 24 also deliver the workpiece W between a transfer mechanism (not illustrated) for the workpiece W and the spin chuck 21.

The guide ring 25 is provided below the workpiece W held by the spin chuck 21 and functions to guide a processing liquid supplied to the surface of the workpiece W toward the drain port. Further, the cup 27 for preventing the scattering of the processing liquid is provided to surround the outer circumference of the guide ring 25. The top of the cup 27 is open to allow for the delivery of the workpiece W to the spin chuck 21. A space that serves as a liquid discharge path is formed between the inner peripheral surface of the cup 27 and the outer circumferential edge of the guide ring 25. Further, the exhaust pipe 28 and the drain port 29 are provided at the bottom of the cup 27 to discharge a liquid moving through the above-described space.

The guide ring 25 is an annular member in a plan view that is formed to extend from the circumferential edge of the aforementioned protective plate 23 toward the cup 27 and is located below the workpiece W held by the spin chuck 21. The lower portion of the guide ring 25 is connected to an inner wall portion of the cup 27, ensuring that the processing liquid does not leak out of the cup 27.

An upper surface of the guide ring 25 includes slopes 25a and 25b. The slope 25a is positioned closer to the center of the cup 27 than the slope 25b. The slope 25a is inclined upward toward the outer side of the cup 27, while the slope 25b is inclined downward toward the outer side of the cup 27. As a result, the guide ring 25 has a mountain-shaped longitudinal cross section.

An upper ring end 26 (annular protrusion) is provided at the boundary between the slope 25a and the slope 25b of the guide ring 25 where the gradients of the slopes 25a and 25b become steeper. The upper ring end 26 is formed to protrude upward, so that it approaches the circumferential edge of that workpiece W while being aligned with the periphery of the workpiece W placed on the aforementioned spin chuck 21. The upper ring end 26 prevents the processing liquid supplied to the surface of the workpiece W from flowing to the backside of the workpiece W and adhering to a position near the center of the workpiece W, or prevents mist of the processing liquid from adhering to a position near the center of the backside of the workpiece W. The guide ring 25 may be changed in position relative to the cup 27. Therefore, the height of the upper ring end 26 relative to the workpiece W and to the spin chuck 21 supporting the workpiece W may be changed.

Further, the coating unit U1 is provided with the processing liquid supplier 31. The processing liquid supplier 31 discharges the processing liquid from above the workpiece W, supported by the spin chuck 21, toward the circumferential edge of the surface of the workpiece W.

The processing liquid supplier 31 includes a nozzle 31a, a processing liquid source 31b, and a pipe 31c. An opening/closing valve controlled by the controller 100 may be provided on the pipe 31c of the processing liquid supplier 31. The opening/closing valve may be configured to switch between the open state and the closed state based on a control signal from the controller 100, thereby switching between the supply and stop of the processing liquid.

The nozzle 31a is attached to, for example, a horizontally extending arm and is movable in the horizontal direction. Further, the nozzle 31a is also movable in the vertical direction. A mover is provided to move the nozzle 31a in both the horizontal and vertical directions, and the nozzle 31a may move between a standby position outside the cup 27 and a position above the workpiece W by the operation of the mover.

Examples of the processing liquid supplied from the processing liquid supplier 31 may include a processing liquid (e.g., resist liquid) used when forming a coating film on the circumferential edge of the workpiece W, a solvent, and others. If it is necessary to supply multiple processing liquids to the workpiece W, a plurality of processing liquid suppliers 31 may be provided within the coating unit U1.

When the controller 100 controls the coating unit U1 described above, it executes a liquid processing for the workpiece W using the processing module 12 according to a predetermined condition. For example, the controller 100 supplies each processing liquid to the workpiece W using the processing liquid supplier 31 based on a predetermined condition and controls the rotation of the workpiece W and others at that time. The controller 100 may include a plurality of functional modules for executing the liquid processing. Each functional module is not limited to one realized by program execution but may also be one realized using a dedicated electric circuit (e.g., logic circuit) or an integrated circuit (Application Specific Integrated Circuit (ASIC)).

### Inspection Wafer and Information Collection Device

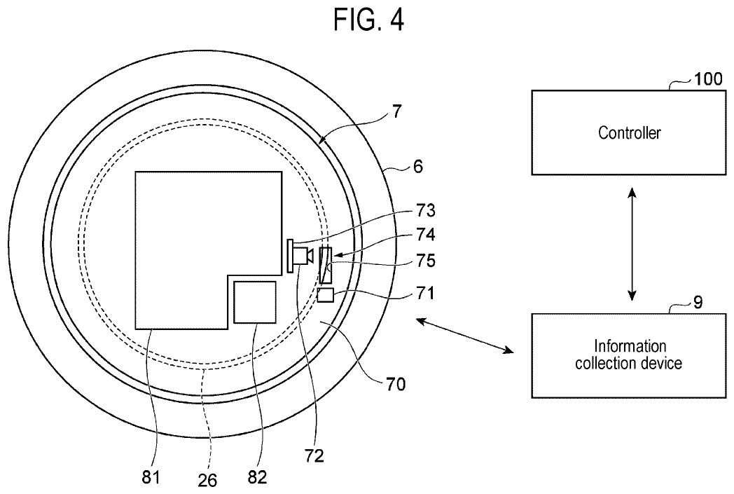

Next, the inspection wafer 7, which is transferred to the coating/development apparatus 2A and is used for the inspection of the coating unit U1, will be described with reference to FIG. 4. The inspection wafer 7 functions to measure the distance between a lower surface of the workpiece W and the upper ring end 26 when the workpiece W is supported by the spin chuck 21. There are cases where the distance between the lower surface of the workpiece W and the upper ring end 26 deviates from an appropriate range during assembling or adjustment of the coating unit U1. If a processing is performed on the workpiece W in such a state, the upper ring end 26 may come into contact with the workpiece W, or may be excessively spaced apart from the workpiece W. To prevent such occurrences, the inspection wafer 7 is transferred, instead of the workpiece W, to the coating unit U1, and in a state where the inspection wafer 7 is supported by the spin chuck 21 in the same manner as the workpiece W, the inspection wafer 7 is used to capture an image of the upper ring end 26, thereby acquiring image data thereof. Then, it calculates the distance between the lower surface of the workpiece W (lower surface of the inspection wafer 7) and the upper ring end 26 from the image data.

The inspection wafer 7 includes a main body 70, a light source 71 (irradiator), a camera 72 (detector), a calculator 73, an optical system 74 (irradiator), a device mounting board 81, and a battery 82. The main body 70 is a circular substrate having the same size as the workpiece W in a plan view. The light source 71, camera 72, calculator 73, optical system 74, device mounting board 81, and battery 82 are provided on that main body 70. The main body 70 is transferred using the transfer mechanism, the support pins 24 of the coating unit U1, and others, similar to the workpiece W. A lower surface of the main body 70 is configured as a flat surface to allow the backside center to be suction-held by the spin chuck 21, similar to the lower surface of the workpiece W. In addition, FIG. 4 and others illustrate the inspection wafer 7 in a state where it is held by the spin chuck 21.

Although described in detail later, the inspection wafer 7 directs line light L1 (strip-shaped light) from the light source 71 to reach an upper surface of the upper ring end 26. Further, it captures an image of a bright line, which is created when the line light L1 reaches the upper surface of the upper ring end 26, using the camera 72. The optical system 74 is arranged to ensure that the line light L1 reaches the upper ring end 26 and that the camera 72 captures the image of the bright line. Further, the calculator 73 functions to estimate the distance between the lower surface of the workpiece W (lower surface of the inspection wafer 7) and the upper ring end 26 based on the image data captured by the camera 72. In this way, the light source 71, camera 72, calculator 73, and optical system 74 function as a distance estimator that estimates the distance between the main body 70 and the upper ring end 26. Further, the light source 71 and optical system 74 function as an irradiator for directing the line light L1 to reach the upper surface of the upper ring end 26.

The device mounting board 81 is provided on a central portion of the main body 70. The camera 72 and calculator 73 may be connected to the device mounting board 81 via cables (not illustrated). At this time, the image data acquired by the camera 72 and calculation results from the calculator 73 may be transmitted to the device mounting board 81 via cables. The device mounting board 81 includes a plurality of boards including, for example, digital signal processor (DSP) boards, but is illustrated as a single board for convenience, and various devices are mounted thereon. Examples of these devices include a device to switch on or off light irradiation using the light source 71, an imaging device using the camera 72, a device (transmitter) for the transmission of the calculation results from the calculator 73 to the information collection device 9, and others, which are based on wireless reception of signals from the information collection device 9. Further, the battery 82 is provided on the central portion of the main body 70 to supply power to each of the light source 71, camera 72, each device included in the device mounting board 81, and others.

The device mounting board 81 may include a plurality of functional modules for executing the above-described processing in the inspection wafer 7. Each functional module is not limited to one realized by program execution but may also be one realized using a dedicated electric circuit (e.g., logic circuit) or an integrated circuit (Application Specific Integrated Circuit (ASIC)).

The inspection wafer 7 operates based on instructions from the information collection device 9 and transmits the operation results to the information collection device 9. In this way, the inspection wafer 7 communicates with the information collection device 9, acquiring instructions from the information collection device 9, and, based on these instructions, performs operations related to image data acquisition and calculation to estimate the distance between the lower surface of the workpiece W (lower surface of the inspection wafer 7) and the upper ring end 26. Furthermore, the calculation results from the inspection wafer 7 are transmitted to the information collection device 9.

Meanwhile, the information collection device 9 interacts with the controller 100, and functions to operate the inspection wafer 7 at an appropriate timing. Information of the controller 100 indicating the transfer status of the inspection wafer 7, particularly, information that the inspection wafer 7 has been transferred to the coating unit U1, is transmitted from the controller 100 to the information collection device 9. The information collection device 9 controls the inspection wafer 7 based on this notification from the controller 100, thereby causing the inspection wafer 7 to perform imaging and calculation to estimate the distance between the lower surface of the inspection wafer 7 and the upper ring end 26. After collecting the estimation results from the inspection wafer 7, the information collection device 9 judges whether the results fall within a predetermined reference value range, and determines whether to proceed with a subsequent processing or not based on the judged result.

The information collection device 9 may include a plurality of functional modules for enabling the transmission and reception of information between the controller 100 and the inspection wafer 7, the judgment of the information collection device 9 based on inspection results from the inspection wafer 7, and others. Each functional module is not limited to one realized by program execution but may also be one realized using a dedicated electric circuit (e.g., logic circuit) or an integrated circuit (Application Specific Integrated Circuit (ASIC)).

### Hardware Configuration of Controller, Inspection Wafer, and Information Collection Device

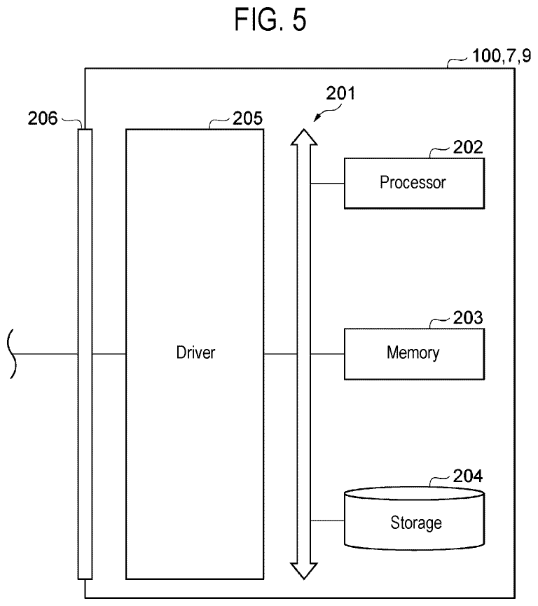

The hardware of the controller 100, the inspection wafer 7 (particularly, the device mounting board 81), and the information collection device 9 may include, for example, a single control computer or a plurality of control computers. Each of the controller 100, the inspection wafer 7, and the information collection device 9 includes a circuit 201 as a component of the hardware, as illustrated in FIG. 5. The circuit 201 may be configured with an electrical circuitry. The circuit 201 may include a processor 202, a memory 203, a storage 204, a driver 205, and an input/output port 206.

The processor 202 executes a program in cooperation with at least one of the memory 203 and the storage 204, and executes the input and output of signals through the input/output port 206, thereby constituting each functional module described above. The memory 203 and storage 204 store various types of information and programs used by the controller 100, inspection wafer 7, and information collection device 9. The driver 205 is a circuit that drives functional elements related to each of the controller 100, the inspection wafer 7, and the information collection device 9. The input/output port 206 performs the input and output of signals between the driver 205 and the related functional elements.

In addition, the substrate processing system 2 may include a single controller 100, or may include a controller group (controller) composed of a plurality of controllers 100. If the substrate processing system 2 includes a controller group, for example, each of a plurality of functional modules may be implemented by a different controller, or may be implemented by a combination of two or more controllers 100. If the controller 100 includes a plurality of computers (circuits 201), each of a plurality of functional modules may be implemented by one computer (circuit 201). Further, the controller 100 may be realized by a combination of two or more computers (circuits 201). The controller 100 may include a plurality of processors 202. In this case, each of a plurality of functional modules may be implemented by a single processor 202, or may be implemented by a combination of two or more processors 202. Part of functions of the controller 100 in the substrate processing system 2 may be provided in a device other than the substrate processing system 2, and that device may be connected to the substrate processing system 2 via a network to realize various operations according to the present embodiment. For example, if functions of the processor 202, the memory 203, and the storage 204 of a plurality of substrate processing systems 2 are integrated and implemented by a single device or a plurality of separate devices, it also becomes possible to manage and control information or operations of the plurality of substrate processing systems 2 remotely and collectively.

### Detailed Structure of Distance Estimator of Inspection Wafer

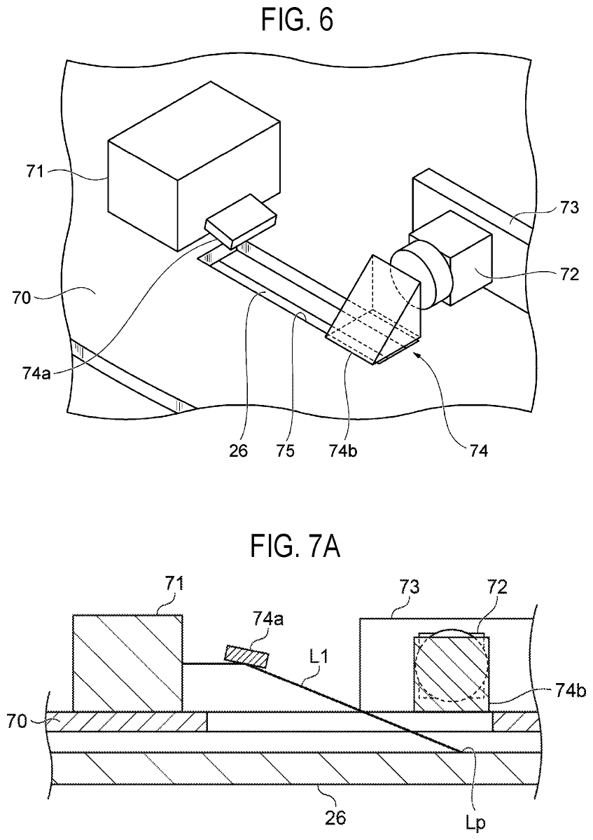

The distance estimator of the inspection wafer 7 will be described with reference to FIGS. 6 to 8B.

A through-hole 75 is formed in the circumferential edge of the main body 70 of the inspection wafer 7 at a position spaced in the circumferential direction of the main body 70. The through-hole 75 is elongated to extend in the tangential direction of the main body 70, and is positioned to correspond to the upper ring end 26 in a plan view when the inspection wafer 7 is supported by the spin chuck 21. The camera 72 functioning as an imaging device and the calculator 73 connected to the camera 72 are provided at positions closer to the center of the main body 70 than the through-hole 75. The field of view of the camera 72 is directed toward the peripheral end side of the main body 70.

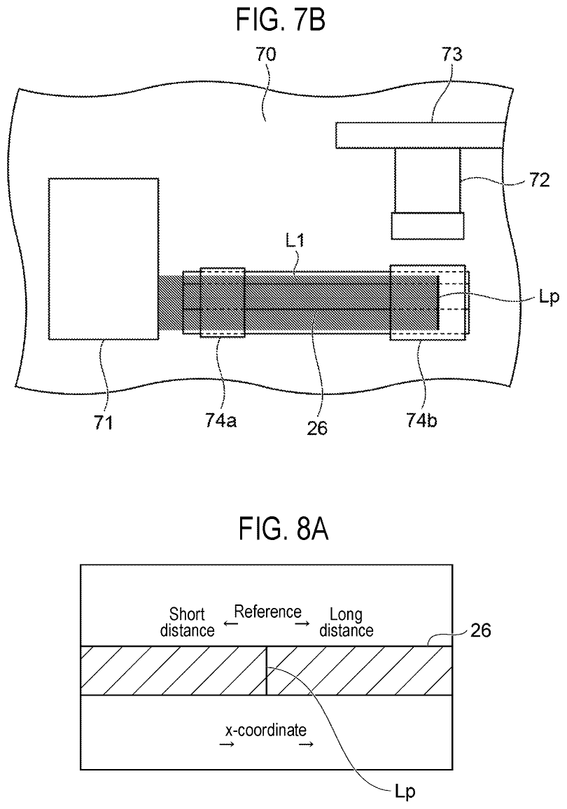

The light source 71 emits line-shaped light. The light source 71 may be configured with, for example, a laser light source. In the example illustrated in FIGS. 6 to 8B, the line light L1 is emitted from the light source 71 to extend in a direction parallel to a main surface of the main body 70. As illustrated in FIG. 7B, the length (in the longitudinal direction) of the line light L1 is set to be greater than the width (in the radial direction) of the upper ring end 26. This is intended to ensure that the line light L1 will reach the upper ring end 26 even if the relative position between the upper ring end 26 and the inspection wafer 7 is slightly changed. The line light L1 is reflected by a mirror 74a, which is part of the optical system, and is emitted downward, i.e., toward the spin chuck 21, thereby reaching the upper surface of the upper ring end 26 located below the main body 70 through the through-hole 75 (see FIG. 7A).

On the other hand, a prism 74b, which is part of the optical system, is positioned on the optical axis of the camera 72. The prism 74b captures an image of the upper ring end 26 and the surroundings thereof below the main body 70 through the through-hole 75. Accordingly, the camera 72 is capable of capturing an image of an area below the main body 70 via the through-hole 75 and the prism 74b. When the inspection wafer 7 is held by the spin chuck 21, the prism 74b is located above the upper ring end 26, allowing the camera 72 to capture an image of a portion of the upper surface of the upper ring end 26 in the circumferential direction.

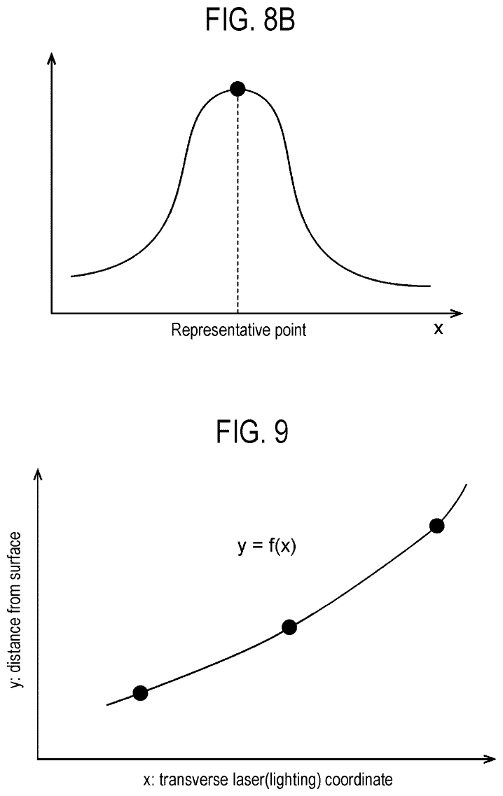

FIG. 8A schematically illustrates an example of image data acquired through imaging described above. As illustrated in FIG. 7A, the line light L1 reaches the upper ring end 26 by way of the mirror 74a. At this time, as illustrated in FIG. 7B, a bright line Lₚ, at which irradiation intensity of the line light L1 is increased can be formed on the surface of the upper ring end 26 at a position where the line light L1 reaches.

Meanwhile, the camera 72 captures an image of the surface of the upper ring end 26 via the prism 74b, thereby acquiring image data on the distribution of scattered light from the line light L1. Accordingly, as illustrated in FIG. 8A, the camera 72 captures an image where the bright line Lₚ corresponding to the line light L1 appears on the upper ring end 26. Further, as illustrated in FIG. 8B, it is assumed that the distribution of light on the upper ring end 26 shows a peak in light intensity (representative point) at a position corresponding to the bright line Lₚ when the direction in which the upper ring end 26 extends is denoted as the x-coordinate.

Here, the line light L1 is emitted in an inclined direction, not perpendicular to the surface of the upper ring end 26. Therefore, if the distance between the main body 70 and the upper ring end 26 is less than the reference (distance corresponding to a set value), the line light L1 will reach the upper ring end 26 at an earlier stage (i.e., with a shorter optical path) than the state illustrated in FIG. 7A. On the other hand, if the distance between the main body 70 and the upper ring end 26 is greater than the reference, the line light L1 will reach the upper ring end 26 at a later stage (i.e., with a longer optical path) than the state illustrated in FIG. 7A. In other words, the position of the bright line Lₚ appearing on the surface of the upper ring end 26 will change depending on the distance between the main body 70 and the upper ring end 26. Thus, for example, as illustrated in FIG. 8A, the bright line Lₚ will shift in one direction if the distance is less than the reference, while the bright line Lₚ will shift in the other direction if the distance is greater than the reference.

In this way, the position of the bright line Lₚ changes depending on the distance between the main body 70 and the upper ring end 26. The inspection wafer 7 utilizes this feature to identify the position of the bright line Lₚ on the upper ring end 26 in the image data captured by the camera 72 and to estimate the distance between the lower surface of the main body 70 and the upper ring end 26 based on this position.

The calculator 73 estimates the distance between the lower surface of the main body 70 and the upper ring end 26 based on the image data captured by the camera 72. At this time, the calculator 73 prepares a model based on a plurality of image data captured under a known distance between the lower surface of the main body 70 and the upper ring end 26. Specifically, a model is prepared in advance, which identifies a relationship between the x-coordinate, i.e., the position of the bright line Lₚ caused by the line light L1 in the image data, and the distance between the lower surface of the main body 70 and the upper ring end 26. As illustrated in FIG. 9, when the position of the bright line Lₚ caused by the line light L1 in the image data (the coordinate of the representative point in the horizontal direction) is denoted as x and the distance between the lower surface of the main body 70 and the upper ring end 26 is denoted as y, an approximate function y=f(x) that defines a relationship between x and y may be set. This approximate function is prepared in advance as a model for estimating the distance between the lower surface of the main body 70 and the upper ring end 26. Thus, it is possible to estimate the distance between the upper ring end 26 and the lower surface of the main body 70 using the prepared approximate function model based on the position of the bright line Lₚ caused by the line light L1 in the image data that is acquired under an unknown distance between the upper ring end 26 and the lower surface of the main body 70. In addition, there is no need for the model to be singular, and for example, individual models may be manufactured depending on the type of the guide ring 25 provided in the coating unit U1.

### Distance Estimation Method (Information Collection Method)

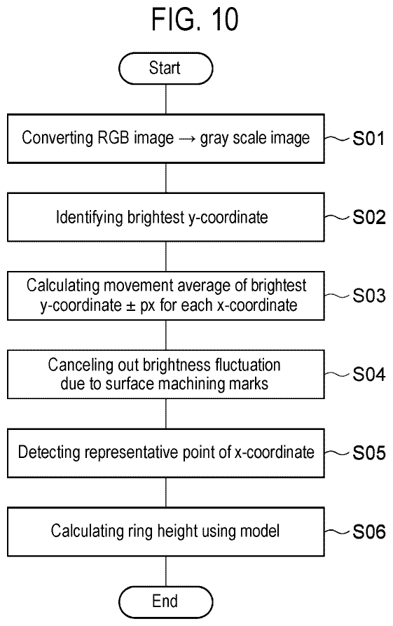

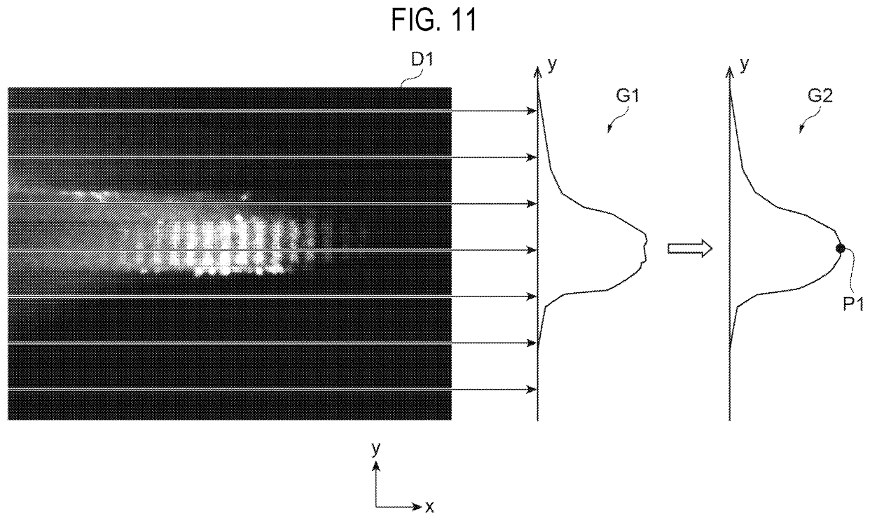

Next, a distance estimation method (information collection method) using the inspection wafer 7, particularly focusing on how the calculator 73 estimates the distance between the lower surface of the main body 70 and the upper ring end 26 from image data will be described with reference to the flowchart of FIG. 10 and the example illustrated in FIGS. 11 to 13B.

In the example illustrated in FIGS. 10 to 13B, a case where the upper ring end 26 is not flat, but has been subjected to surface machining with repeated unevenness in the circumferential direction will be described. If the upper ring end 26 is a flat surface, it is conceivable that it is relatively easy to identify the representative point where the peak in light intensity occurs since the bright line Lₚ appears relatively clearly in the image data captured by the above method. On the other hand, for example, if surface machining marks are formed on the upper ring end 26, as illustrated in an image D1 of FIG. 11, the bright line Lₚ does not appear clearly due to the surface unevenness, and the captured image shows that the line light L1 is also diffused at uneven portions in both sides of the bright line. Therefore, the calculator 73 performs an image processing described below since identify the representative point is not available by simply measuring the intensity of light at each pixel in the image data.

First, in step S01, the calculator 73 converts image data acquired by the camera 72 into a gray scale image. If an image captured by the camera 72 is already in grayscale, this processing may be omitted.

Next, in step S02, the calculator 73 identifies the brightest y-coordinate from the image data. As illustrated in FIG. 11, the image D1 may be represented in the xy-coordinate where the x-axis of each pixel corresponds to the direction along the upper ring end 26 and the y-axis corresponds to the direction perpendicular to the x-axis. However, the image D1 also contains an area where the upper ring end 26 is not captured. Therefore, the calculator 73 calculates the sum of the brightness values of pixels having a same y-coordinate and creates a graph G1, which represents the cumulative brightness values for each y-coordinate when the position of each pixel is denoted as (x, y), as illustrated in FIG. 11. Furthermore, the calculator 73 calculates a movement average of each point ±py point, thereby obtaining a graph G2, which mitigates a fluctuation in the brightness values for each y-coordinate. In the graph G2, the y-coordinate having the largest brightness value can be identified as a representative y-coordinate P1.

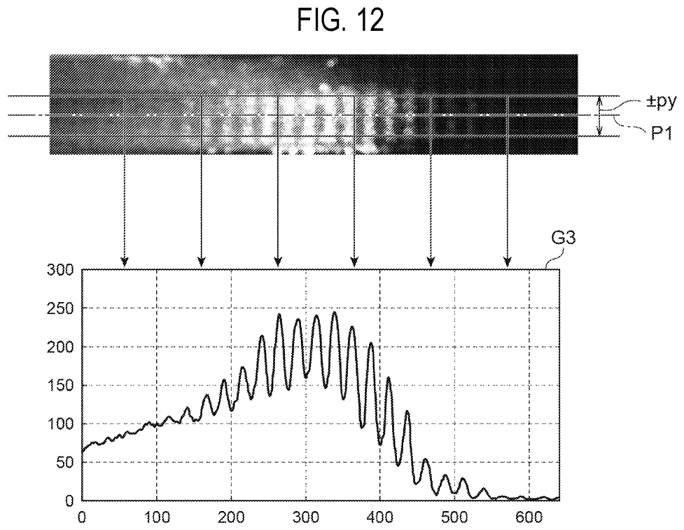

Subsequently, in step S03, the calculator 73 calculates a movement average of the representative y-coordinate P1, obtained in step S02, ±py for each x-coordinate. Specifically, as illustrated in FIG. 12, the calculator 73 calculates an average (movement average) from the brightness values of pixels with the same x-coordinate within the range of the representative y-coordinate P1, identified in step S02, ±py. As a result, as illustrated in a graph G3 of FIG. 12, a graph representing the brightness value average for each x-coordinate is obtained. In the graph G3, the brightness fluctuation caused by the surface unevenness (surface machining marks) of the upper ring end 26, as illustrated in the image D1, is represented as unevenness in the brightness values.

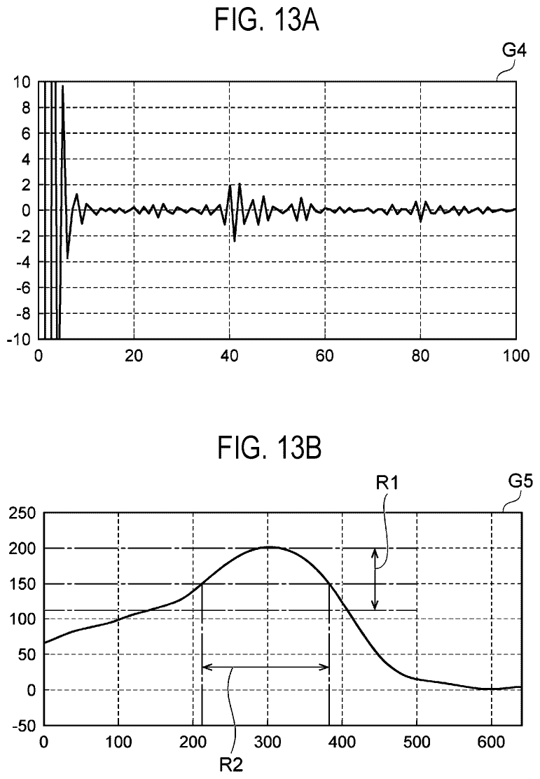

Subsequently, in step S04, the calculator 73 performs a processing to cancel out the brightness fluctuation caused by the surface machining marks. Specifically, it applies Fast Fourier Transformation (FFT) to the brightness value data obtained as the graph G3 to decompose the brightness values included in the graph G3 into frequency components. The result is illustrated as a graph G4 of FIG. 13A. The calculator 73 cuts off high-frequency components (e.g., components having 12 cycles or more) from this result (for zero conversion) and then, performs an inverse FFT. As a result, as illustrated in FIG. 13B, a graph G5 with the high frequency components removed is obtained. Through this processing, the components caused by the continuous unevenness of the surface processing marks are removed.

Subsequently, in step S05, the calculator 73 identifies a representative point based on the graph G5 obtained after the removal of the components caused by the surface machining marks. Although the x-coordinate with the largest brightness value in the graph G5 illustrated in FIG. 13B may be identified as the representative point, for example, the calculator 73 may perform the following sequence to identify, for example, a representative point P2 based on a broader range of information. Specifically, after detecting the maximum brightness value in graph G5 of FIG. 13B, the calculator 73 identifies a range R1 of brightness values exceeding 75% (threshold) of the maximum brightness value and then, identifies an x-coordinate range R2 of the brightness values within the range R1. Then, the calculator 73 may calculate the x-coordinate of the centroid of the brightness value distribution within the range R2 to identify that x-coordinate as the representative point. Through this calculation, the representative point may be calculated in consideration of a variation in x-coordinate brightness values around the x-coordinate where a peak in the brightness value occurs. Further, utilizing information on the range R1 of brightness values exceeding 75% of the maximum brightness value enables the utilization of information on a range where greater waveform symmetry is maintained.

Subsequently, in step S06, the calculator 73 estimates the distance between the lower surface of the main body 70 and the upper ring end 26 by applying the x-coordinate of the representative point obtained in step S05 to the model. As described above, the calculator 73 stores the model in advance, which represents a relationship between the x-coordinate in the image data and the distance between the lower surface of the main body 70 and the upper ring end 26, as illustrated in FIG. 9. The calculator 73 calculates the distance between the lower surface of the main body 70 and the upper ring end 26 by substituting the x-coordinate of the representative point calculated in step S05 into the model.

With the above sequence, the processing of calculating the distance between the lower surface of the main body 70 and the upper ring end 26 based on the image D1 ends.

### Control Method Between Controller-Information Collection Device-Inspection Wafer

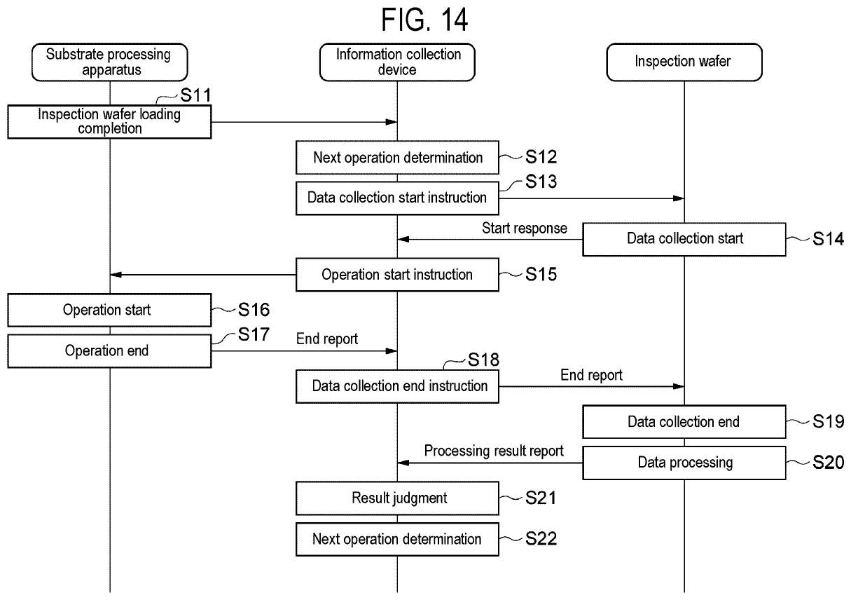

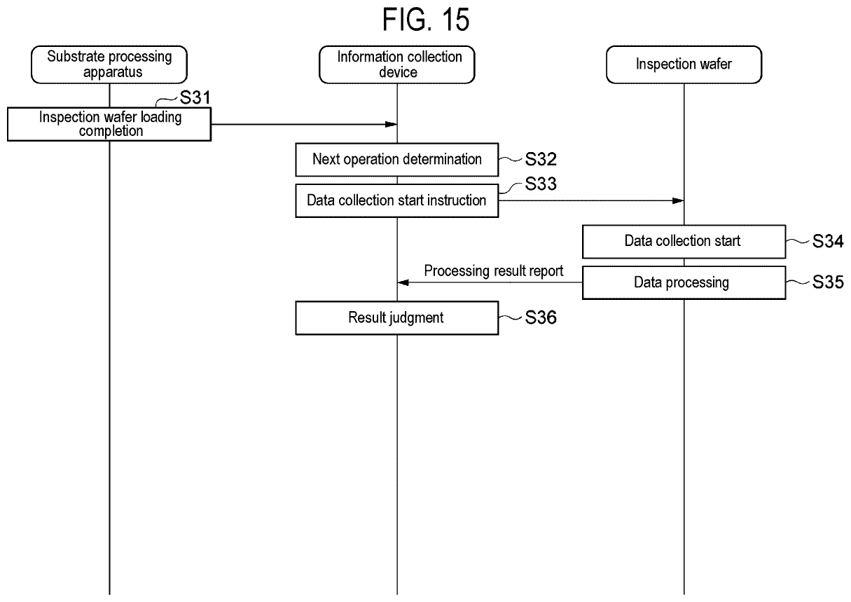

A processing flow between the controller 100 of the coating/development apparatus 2A, the information collection device 9, and the inspection wafer 7 will be described with reference to FIGS. 14 and 15. It is assumed that the controller 100 controls each component of the coating/development apparatus 2A serving as a substrate processing apparatus, and previously has a procedure for transferring the inspection wafer 7 instead of the workpiece W and loading it into the coating unit U1 for inspection, separately from a procedure for performing a substrate processing on the workpiece W. In the following example, it is assumed that the controller 100 executes control when performing inspection using the inspection wafer 7. At this time, the information collection device 9 operates the inspection wafer 7 based on notifications from the controller 100. Further, the inspection wafer 7 performs imaging within the coating unit U1 based on instructions from the information collection device 9, calculating the distance between the lower surface of the main body 70 and the upper ring end 26.

FIG. 14 illustrates a sequence diagram for a case where the information collection device 9 individually instructs the start and end of an operation for the inspection wafer 7.

First, the inspection wafer 7 is transferred and is completely loaded into the coating unit U1 under the control of the controller 100 (step S11). Then, the controller 100 notifies the information collection device 9 of the completion of loading. The information collection device 9 determines a next operation based on the notification from the controller 100 (step S12) and then, instructs the inspection wafer 7 to start data collection (step S13).

The inspection wafer 7 instructs each component to start an operation when the device mounting board 81 acquires the instruction from the information collection device 9. As a result, for example, the light source 71 starts emitting the line light L1, the camera 72 starts repetitive imaging at preset intervals, and the calculator 73 starts the processing of calculating the distance between the lower surface of the main body 70 and the upper ring end 26 from image data (step S14). Further, the device mounting board 81 notifies the information collection device 9 that data collection in the inspection wafer 7 has started. The information collection device 9 judges, based on the notification from the inspection wafer 7, that the inspection wafer 7 is in a ready state and issues an operation start instruction to cause the controller 100 to execute an operation based on a condition for collecting data using the inspection wafer 7 (step S15).

The controller 100 controls the coating unit U1 to start a predetermined operation based on the instruction from the information collection device (step S16) and controls the coating unit U1 to end the predetermined operation after executing it (step S17). At this time, the controller 100 notifies the information collection device 9 that the predetermined operation of the coating unit U1 has ended. The information collection device 9 instructs the inspection wafer 7 to end the data collection operation based on the notification from the controller 100 (step S18). The inspection wafer 7 ends data collection based on the instruction from the information collection device 9 (step S19). Then, it consolidates information to be notified to the information collection device 9 (step S20), and reports the results. As an example, the calculation results of the distance between the lower surface of the main body 70 and the upper ring end 26 for each image calculated by the calculator 73 of the inspection wafer 7 may be summarized and notified to the information collection device 9 through the addition of a predetermined processing.

When receiving the processing results from the inspection wafer 7, the information collection device 9 judges whether the results fall within a preset reference range for the distance between the lower surface of the main body 70 and the upper ring end 26 (step S21). Further, the information collection device 9 may determine a next operation based on the judged result (step S22). For example, if the result of judgment (S21) indicates that the distance between the lower surface of the main body 70 and the upper ring end 26 is within the reference range (OK judgment), the information collection device 9 may be configured to instruct the controller 100 to proceed an unloading operation of the inspection wafer 7. Further, if the result of judgement indicates that the distance between the lower surface of the main body 70 and the upper ring end 26 is not within the reference range (NG judgment), the information collection device 9 may acquire detailed data from the inspection wafer 7 rather than a summary. Then, the information collection device 9 may perform further analysis on the results. In addition, these are merely illustrative and may be changed as appropriate.

FIG. 15 illustrates a sequence diagram for a case where the information collection device 9 issues a set of instructions related to a series of operations to the inspection wafer 7.

First, the inspection wafer 7 is transferred, and is completely loaded into the coating unit U1 under the control of the controller 100 (step S31). Then, the controller 100 notifies the information collection device 9 of the completion of loading. The information collection device 9 determines a next operation based on the notification from the controller 100 (step S32) and instructs the inspection wafer 7 to start data collection (step S33). At this time, the information collection device 9 also notifies the inspection wafer 7 of a condition for ending the data collection. As an example, the information collection device 9 may notify the inspection wafer 7 of a data collection time (time for imaging and calculation) as the condition for ending the data collection. Further, if there is a need to collect images captured by the camera 72 of the inspection wafer 7, the information collection device 9 may instruct the inspection wafer 7 to collect the captured images and to end imaging once a specified number of images (e.g., at least 1 image) have been collected. Then, the inspection wafer 7 may be instructed to transmit the captured images to the information collection device 9.

When the device mounting board 81 acquires the instruction from the information collection device 9, the inspection wafer 7 instructs each component to start an operation. As a result, for example, the light source 71 starts emitting the line light L1, and the camera 72 starts imaging under a preset condition. Furthermore, the calculator 73 starts the processing of calculating the distance between the lower surface of the main body 70 and the upper ring end 26 from the image data when instructed by the information collection device 9 (step S34). Once data collection under the preset condition has ended, the inspection wafer 7 consolidates information to be notified to the information collection device 9 (step S35), and reports the results.

When receiving the processing results from the inspection wafer 7, the information collection device 9 may judge whether the results fall within a preset reference range for the distance between the lower surface of the main body 70 and the upper ring end 26 (step S36). Further, if the objective is to collect data from the inspection wafer 7 (e.g., to acquire images), the information collection device 9 may perform a next operation without making a judgment. A subsequent processing may be changed appropriately according to later stages of processing, similar to the case illustrated in FIG. 14.

### Actions

According to the above information collection system 1 and information collection method, the light source 71, which serves as an irradiator fixed to the disk-shaped main body 70, emits the line light L1 as a measurement wave to the upper ring end 26 in the form of an annular member. Further, the camera 72, which serves as a detector fixed to the main body 70, detects a response to the measurement wave from the irradiator. Furthermore, the calculator 73 acquires information on the gap between the main body and the annular member based on the detected response. Since the main body 70 may be held by the spin chuck 21 serving as a substrate holder, this configuration allows for the acquisition of information on the distance between a functional member and a substrate within a substrate processing apparatus.

Further, when using light as a measurement wave as described above, the calculator 73 acquires information on the gap between the main body 70 and the upper ring end 26 using images captured by the camera 72. With a configuration where various types of information contained in the images are utilized to acquire the gap information, it is possible to acquire more accurate information on the distance between the functional member and the substrate within the substrate processing apparatus.

Furthermore, the light emitted from the irradiator may be the line light L1 (strip-shaped light). At this time, the annular member may be irradiated with the line light L1 from a direction other than perpendicular to the upper end of the annular member, such that the light extends in a direction intersecting the circumferential direction of the annular member. With this configuration, in an embodiment, the calculator 73 may identify a light irradiation position of the strip-shaped light on the annular member from the images captured by the camera 72, and may acquire information on the gap between the main body and the annular member based on the identified information.

Using the strip-shaped light makes it easier to irradiate the annular member with the strip-shaped light even if the relative position between the annular member and the main body 70 changes slightly. Further, when the annular member is irradiated with the strip-shaped light from a direction other than perpendicular to the upper end of the annular member, the light irradiation position of the strip-shaped light on the annular member changes depending on the distance between the main body 70 and the annular member. Therefore, as described in the above embodiment, the calculator 73 is configured to identify the light irradiation position of the strip-shaped light on the annular member and to calculate the distance between the main body and the annular member based on the identified information. Thus, it is possible to acquire more accurate information on the distance between the functional member and the substrate within the substrate processing apparatus.

In an embodiment, the calculator may acquire information on the distance between the main body and the annular member based on a model that illustrates a relationship between the light irradiation position of the strip-shaped light on the annular member and the distance between the main body and the annular member. With this configuration, it is possible to acquire more accurate information on the distance between the functional member and the substrate within the substrate processing apparatus.

The calculator 73 may calculate a change in the intensity distribution of light in the circumferential direction of the annular member from information related to the intensity distribution of light included in the images captured by the camera 72, and may identify the light irradiation position of the strip-shaped light on the annular member from information on that change.

Further, as described in the above embodiment, the upper surface of the annular member may have repeated unevenness along the circumferential direction. In an embodiment, the calculator 73 may apply Fast Fourier Transform to the images captured by the camera to remove frequency components of the light intensity that are repeated along the circumferential direction of the annular member, and may identify the light irradiation position of the strip-shaped light on the annular member.

If the upper surface of the annular member has repeated unevenness along the circumferential direction, scattered light due to this unevenness may make it difficult to accurately identify the light irradiation position of the strip-shaped light. In such a case, using Fast Fourier Transform as described above to remove the frequency components as described allows for more accurate identification of the light irradiation position of the strip-shaped light.

The annular member may be a liquid processing cup that is located in the backside of the substrate and includes a backside liquid receiving portion with a protrusion designed to prevent a processing liquid supplied to the substrate from flowing to the backside of the substrate. At this time, the gap between the main body 70 and the annular member may correspond to the gap between the main body 70 and the protrusion of the backside liquid receiving portion. In addition, the backside liquid receiving portion corresponds to the guide ring 25 described earlier, and the upper ring end 26 of the guide ring 25 corresponds to the above-described protrusion. Since the upper ring end 26 is a member positioned in proximity to the workpiece W as described above, accurately determining the distance between them is required. Therefore, by using the above configuration, it is possible to more accurately determine the distance between the substrate and the upper ring end.

### Modifications

While various exemplary embodiments have been described above, various omissions, substitutions, and changes may be made without being limited to the exemplary embodiments described above. Further, elements from different embodiments may be combined to form other embodiments.

For example, while the above embodiment has described a configuration for irradiating the upper ring end 26 with the line light L1, the line light L1 may be realized using various types of light other than laser light. Further, the measurement wave is not limited to light, but may also be sound waves such as ultrasound. Thus, the types of measurement wave are not limited. In addition, an appropriate device may be selected as a detector based on the types of measurement wave.

Further, while the above embodiment has described an example where the inspection wafer 7 is equipped with the calculator 73, it is also possible for a function corresponding to the calculator 73 to be provided in the information collection device 9. In this case, a configuration where image information of the camera 72 is transmitted directly from the inspection wafer 7 to the information collection device 9 is also possible.

Further, while the above embodiment has described a case of measuring the distance between the substrate and the annular member, a target functional member may be other members included in the substrate processing apparatus. As an example, the inspection wafer described in the above embodiment may be used to measure the distance (gap) between an arm that transfers the workpiece W into the coating/development apparatus 2A and the workpiece W.

Further, it will be understood from the above description that various embodiments of the present disclosure have been set forth herein for purpose of illustration, and that various changes may be made without departing from the scope and spirit of the present disclosure. Accordingly, the various embodiments disclosed herein are not intended to be limiting, and the true scope and spirit are indicated by the appended claims.

### EXPLANATION OF REFERENCE NUMERALS

1: information collection system, 2: substrate processing system, 2A: coating/development apparatus, 2B: exposure apparatus, 7: inspection wafer (inspection substrate), 9: information collection device, 21: spin chuck (substrate holder), 25: guide ring, 26: upper ring end, 27: cup, 70: main body, 71: light source, 72: camera, 73: calculator, 74: optical system, 74a: mirror, 74b: prism, 75: through-hole, 81: device mounting board, 82: battery, 100: controller (control unit)

1. An information collection system that acquires information on a substrate processing apparatus comprising a substrate holder configured to hold a substrate and an annular member located in a backside of the substrate, the information collection system comprising:
a disk-shaped main body having a bottom surface that is capable of being held by the substrate holder;
an irradiator fixed to the main body and configured to irradiate the annular member with a measurement wave;
a detector fixed to the main body and configured to detect a response to the measurement wave from the irradiator; and
a calculator configured to acquire information on a gap between the main body and the annular member based on the response detected by the detector.

2. The information collection system of claim 1, wherein the irradiator emits light as the measurement wave, and
wherein the detector is a camera that captures an image of the annular member irradiated with the light.

3. The information collection system of claim 2, wherein the light emitted from the irradiator is strip-shaped light,
wherein the annular member is irradiated with the strip-shaped light from a direction other than perpendicular to an upper end of the annular member, such that the light extends in a direction intersecting a circumferential direction of the annular member, and
wherein the calculator identifies a light irradiation position of the strip-shaped light on the annular member from the image captured by the camera, and acquires the information on the gap between the main body and the annular member based on the identified information.

4. The information collection system of claim 3, wherein the calculator acquires the information on the gap between the main body and the annular member based on a model that illustrates a relationship between the light irradiation position of the strip-shaped light on the annular member and the gap between the main body and the annular member.

5. The information collection system of claim 3, wherein the calculator calculates a change in light intensity distribution in a circumferential direction of the annular member from information on the light intensity distribution included in the image captured by the camera, and identifies the light irradiation position of the strip-shaped light on the annular member from the change information.

6. The information collection system of claim 5, wherein an upper surface of the annular member contains repeated unevenness along the circumferential direction, and
wherein the calculator applies Fast Fourier Transform to the image captured by the camera to remove, from the image, a frequency component of an intensity of light that is repeated along the circumferential direction of the annular member, and identifies the light irradiation position of the strip-shaped light on the annular member.

7. The information collection system of claim 1, wherein the annular member is a liquid processing cup that is located in the backside of the substrate and includes a backside liquid receiving portion with a protrusion designed to prevent a processing liquid supplied to the substrate from flowing to the backside of the substrate, and
wherein the gap between the main body and the annular member is a gap between the main body and the protrusion of the backside liquid receiving portion.

8. The information collection system of claim 1, further comprising:
an information collection device capable of communicating with a controller that controls the substrate processing apparatus; and
an inspection substrate capable of communicating with the information collection device and including the main body, the irradiator, and the detector,
wherein the irradiator and the detector operate based on an instruction from the information collection device.

9. The information collection system of claim 8, wherein the calculator is provided in the inspection substrate, and operates based on the instruction from the information collection device.

10. The information collection system of claim 8, wherein the calculator is provided in the information collection device.

11. An inspection substrate that acquires information on a substrate processing apparatus comprising a substrate holder configured to hold a substrate and an annular member located in a backside of the substrate, the inspection substrate comprising:
a disk-shaped main body having a bottom surface that is capable of being held by the substrate holder;
an irradiator fixed to the main body and configured to irradiate the annular member with a measurement wave; and
a detector fixed to the main body and configured to detect a response to the measurement wave from the irradiator.

12. The inspection substrate of claim 11, further comprising a calculator configured to acquire information on a gap between the main body and the annular member based on the response detected by the detector.

13. An information collection method of acquiring information on a substrate processing apparatus comprising a substrate holder configured to hold a substrate and an annular member located in a backside of the substrate, the information collection method comprising:
holding a bottom surface of a disk-shaped main body by the substrate holder;
irradiating the annular member with a measurement wave using an irradiator fixed to the main body;
detecting a response to the measurement wave from the irradiator using a detector fixed to the main body; and
acquiring information on a gap between the main body and the annular member using a calculator based on the response detected by the detector.

14. The information collection method of claim 13, wherein in the irradiating, the irradiator emits light as the measurement wave, and
wherein the detector is a camera that captures an image of the annular member irradiated with the light.

15. The information collection method of claim 14, wherein in the irradiating, the light emitted from the irradiator is strip-shaped light,
wherein the annular member is irradiated with the strip-shaped light from a direction other than perpendicular to an upper end of the annular member, such that the light extends in a direction intersecting a circumferential direction of the annular member, and
wherein in the acquiring, the calculator identifies a light irradiation position of the strip-shaped light on the annular member from the image captured by the camera, and acquires the information on the gap between the main body and the annular member based on the identified information.

16. The information collection method of claim 15, wherein in the acquiring, the calculator acquires the information on the gap between the main body and the annular member based on a model that illustrates a relationship between the light irradiation position of the strip-shaped light on the annular member and the gap between the main body and the annular member.

17. The information collection system of claim 15, wherein in the acquiring, the calculator calculates a change in light intensity distribution in a circumferential direction of the annular member from information on the light intensity distribution included in the image captured by the camera, and identifies the light irradiation position of the strip-shaped light on the annular member from the change information.

18. The information collection method of claim 17, wherein an upper surface of the annular member contains repeated unevenness along the circumferential direction, and
wherein in the acquiring, the calculator applies Fast Fourier Transform to the image captured by the camera to remove, from the image, a frequency component of an intensity of light that is repeated along the circumferential direction of the annular member, and identifies the light irradiation position of the strip-shaped light on the annular member.

19. The information collection system of claim 4, wherein the calculator calculates a change in light intensity distribution in a circumferential direction of the annular member from information on the light intensity distribution included in the image captured by the camera, and identifies the light irradiation position of the strip-shaped light on the annular member from the change information.

20. The information collection system of claim 19, wherein an upper surface of the annular member contains repeated unevenness along the circumferential direction, and
wherein the calculator applies Fast Fourier Transform to the image captured by the camera to remove, from the image, a frequency component of an intensity of light that is repeated along the circumferential direction of the annular member, and identifies the light irradiation position of the strip-shaped light on the annular member
